(19) United States
(12) Patent Application Publication
(10) Pub. No.: US 2024/0294795 A1
(43) Pub. Date: Sep. 5, 2024

(54) HARDMASK COMPOSITION, HARDMASK LAYER AND METHOD OF FORMING PATTERNS

(71) Applicant: SAMSUNG SDI CO., LTD., Yongin-si (KR)

(72) Inventors: Huiseon CHOE, Suwon-si (KR); Sunghwan KIM, Suwon-si (KR)

(21) Appl. No.: 18/408,858

(22) Filed: Jan. 10, 2024

(30) Foreign Application Priority Data
Feb. 14, 2023 (KR) 10-2023-0019582

(51) Int. Cl. C09D 165/00; G03F 7/11

(52) U.S. Cl. CPC C09D 165/00; G03F 7/11

(57) ABSTRACT

A hardmask composition, a hardmask layer including a cured product of the hardmask composition, and a method of forming patterns using the hardmask layer including a cured product of the hardmask composition, the hardmask composition including a compound represented by Chemical Formula 1; and a solvent,

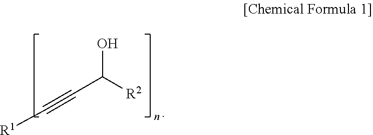

### CROSS-REFERENCE TO RELATED APPLICATION

This application claims priority to and the benefit of Korean Patent Application No. 10-2023-0019582 filed in the Korean Intellectual Property Office on Feb. 14, 2023, the entire contents of which are incorporated herein by reference.

### BACKGROUND

### 1. Field

Embodiments relate to a hardmask composition, a hardmask layer, and a method of forming patterns.

### 2. Description of the Related Art

Recently, the semiconductor industry has developed to an ultra-fine technique having a pattern of, e.g., several to several tens nanometer size. Such ultrafine technique may use effective lithographic techniques. Some lithographic techniques may include providing a material layer on a semiconductor substrate; coating a photoresist layer thereon; exposing and developing the same to provide a photoresist pattern; and etching a material layer using the photoresist pattern as a mask.

### SUMMARY

The embodiments may be realized by providing a hardmask composition including a compound represented by Chemical Formula 1; and a solvent,

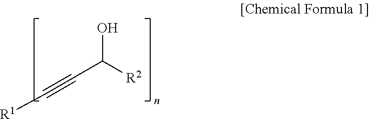

wherein, in Chemical Formula 1, R¹ is a substituted or unsubstituted C6 to C20 aromatic hydrocarbon group, R² is a substituted or unsubstituted C6 to C30 aromatic hydrocarbon group, a substituted or unsubstituted C3 to C30 heteroaromatic group, or a combination thereof, n is an integer of greater than or equal to 1 and does not exceed the valency of R¹, and when n is an integer of 2 or more, each R² is the same or different from each other.

In Chemical Formula 1, R² may be a substituted or unsubstituted C10 to C30 aromatic hydrocarbon group, a substituted or unsubstituted C6 to C30 heteroaromatic group, or a combination thereof.

In Chemical Formula 1, R¹ may be a substituted or unsubstituted C6 to C14 aromatic hydrocarbon group, R² is a substituted or unsubstituted C10 to C30 aromatic hydrocarbon group, and n is 2.

In Chemical Formula 1, R¹ may be a substituted or unsubstituted C6 to C20 aromatic hydrocarbon group of a moiety of Group 1:

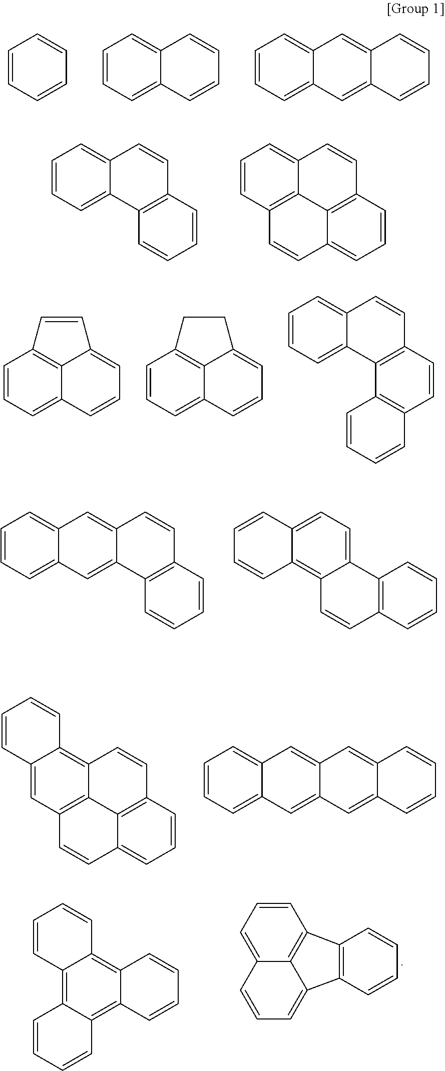

In Chemical Formula 1, R² may be a substituted or unsubstituted C6 to C30 aromatic hydrocarbon group of a moiety of Group 2 or a substituted or unsubstituted C3 to C30 heteroaromatic group of a moiety of Group 3:

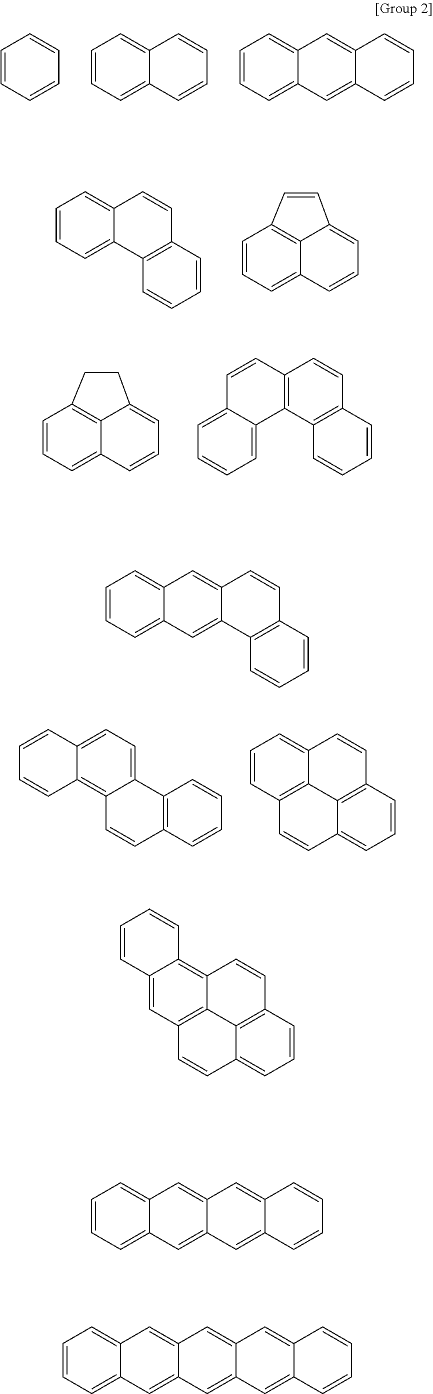

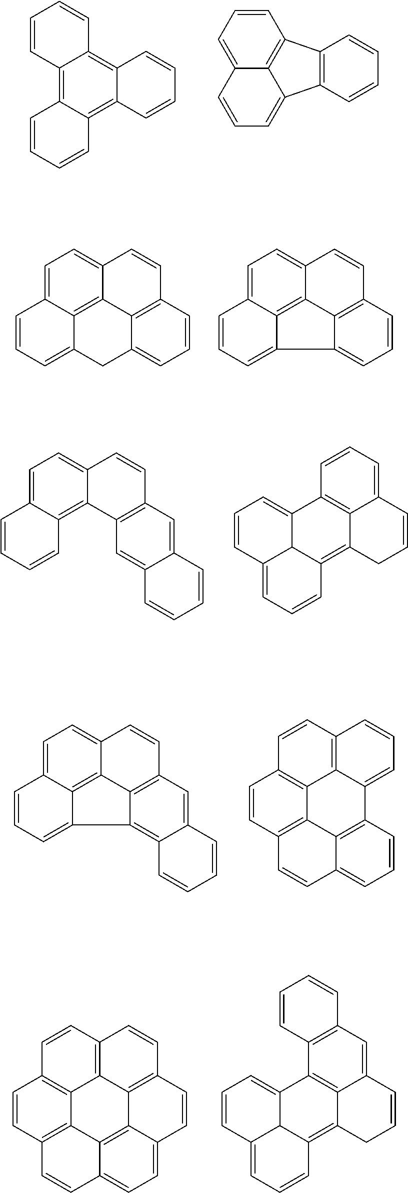

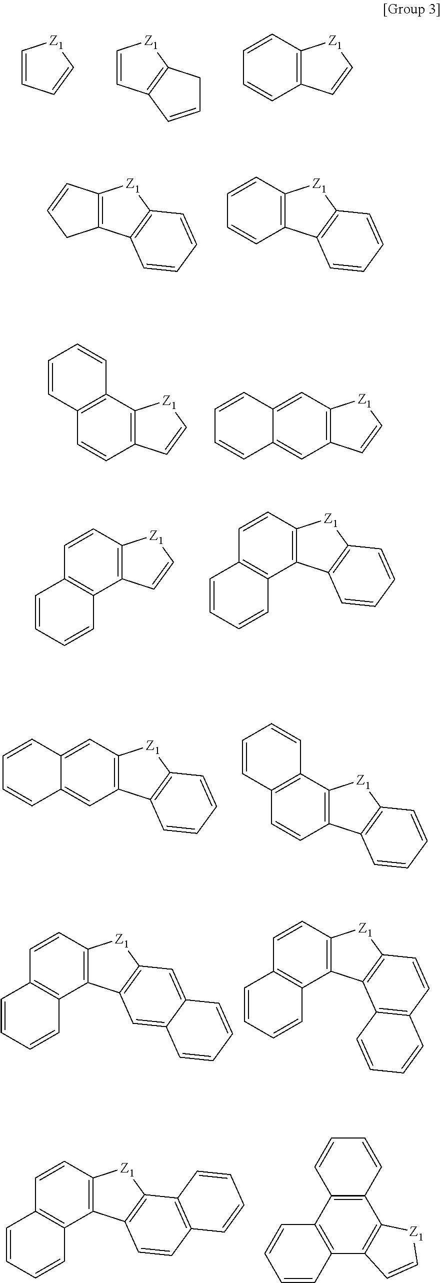

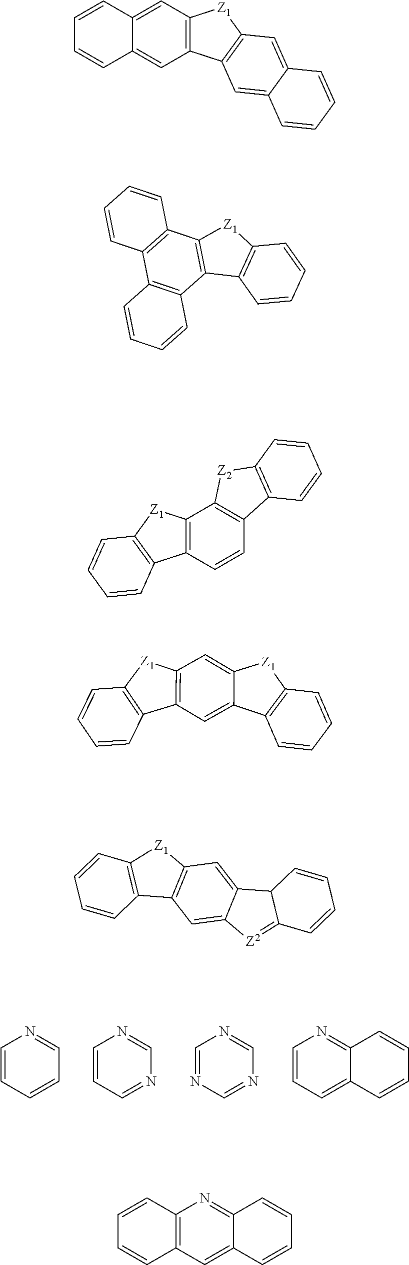

in Group 3, Z¹ and Z² may each independently be —O—, —S—, —NR′—, in which R′ is hydrogen, deuterium, or a substituted or unsubstituted C1 to C10 alkyl group, or a combination thereof.

In Chemical Formula 1, R¹ may be substituted or unsubstituted C6 to C20 aromatic hydrocarbon group of a moiety of Group 1-1, and R² may be a substituted or unsubstituted C6 to C30 aromatic hydrocarbon group of a moiety of Group 2-1,

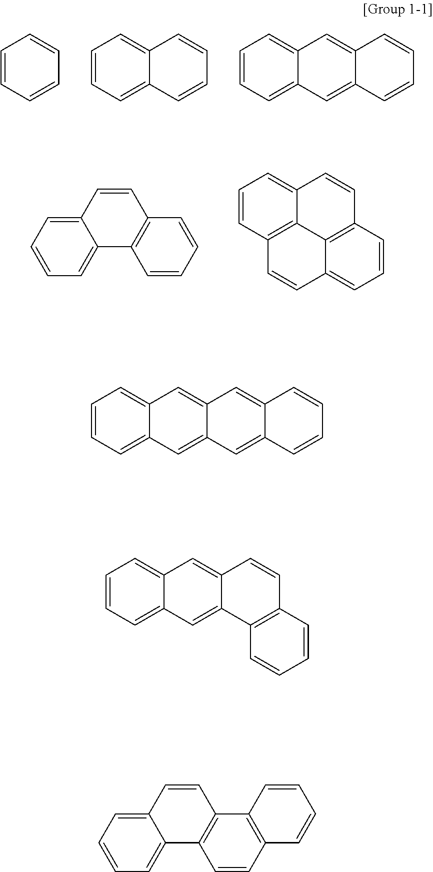

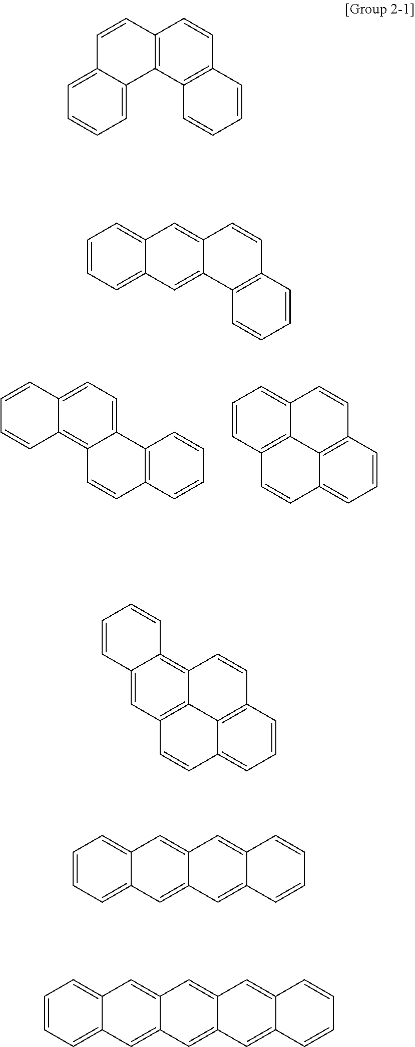

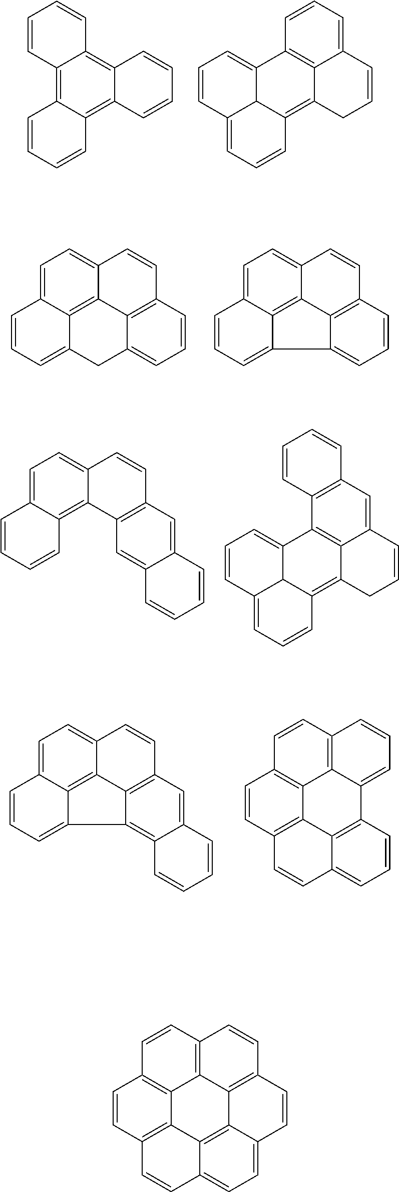

In Chemical Formula 1, n may be 2 and each R² may be the same.

The compound represented by Chemical Formula 1 may be represented by one of Chemical Formula 1-1 to Chemical Formula 1-3:

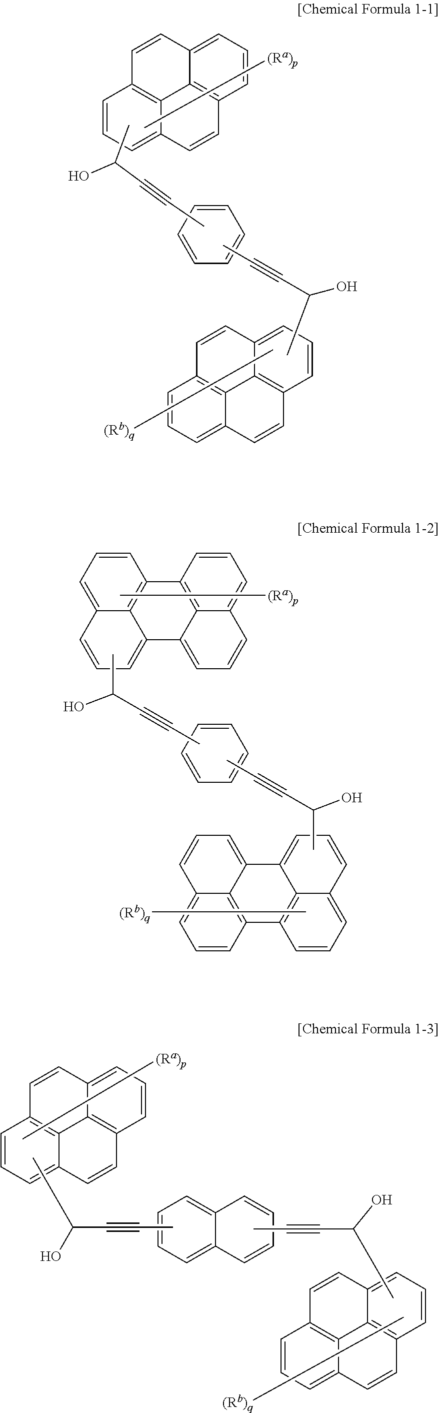

in Chemical Formula 1-1 to Chemical Formula 1-3, R^{a} and R^{b} may each independently be a hydroxy group, a substituted or unsubstituted C1 to C5 alkoxy group, a halogen atom, an amino group, a thiol group, or a combination thereof, and p and q may each independently be an integer of 0 to 10.

The compound may have a molecular weight of about 300 g/mol to about 5,000 g/mol.

The compound may be included in an amount of about 0.1 wt % to about 30 wt %, based on a total weight of the hardmask composition.

The solvent ma include propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

The embodiments may be realized by providing a hardmask layer comprising a cured product of the hardmask composition according to an embodiment.

The embodiments may be realized by providing a method of forming patterns, the method including providing a material layer on a substrate; applying the hardmask composition according to an embodiment to the material layer; heat-treating the hardmask composition to form a hardmask layer; forming a photoresist layer on the hardmask layer; exposing and developing the photoresist layer to form a photoresist pattern; selectively removing the hardmask layer using the photoresist pattern to expose a portion of the material layer; and etching an exposed part of the material layer.

Forming the hardmask layer may include heat-treating at about 100° C. to about 1,000° C.

### DETAILED DESCRIPTION OF THE EMBODIMENTS

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. As used herein, hydrogen substitution (—H) may include deuterium substitution (-D) or tritium substitution (-T). For example, any hydrogen in any compound described herein may be protium, deuterium, or tritium (e.g., based on natural or artificial substitution). As used herein, the term “or” is not necessarily an exclusive term, e.g., “A or B” would include A, B, or A and B.

In addition, adjacent two substituents of the substituted halogen atom (F, Br, C1, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, when a definition is not otherwise provided, “aromatic hydrocarbon” refers to a group having one or more hydrocarbon aromatic moieties, including a form in which hydrocarbon aromatic moieties are linked by a single bond, a non-aromatic fused ring form in which hydrocarbon aromatic moieties are fused directly or indirectly, or a combination thereof as well as non-fused aromatic hydrocarbon rings, fused aromatic hydrocarbon rings.

More specifically, a substituted or unsubstituted aromatic hydrocarbon ring may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a combination thereof, or a combined fused ring of the foregoing groups, but is not limited thereto.

As used herein, when a definition is not otherwise provided, “hetero” means containing one or more hetero atoms selected from N, O, S, Se, and P.

As used herein, when a definition is not otherwise provided, a “heteroaromatic” means containing at least one atom selected from N, O, S, Se, and P instead of carbon (C) in the aromatic hydrocarbon rings. Two or more heteroaromatic rings may be directly linked through a sigma bond or fused to each other. When the heteroaromatic rings are fused rings, all or each of the fused rings may include 1 to 3 hetero atoms.

As used herein, the polymer may include both an oligomer and a polymer.

Unless otherwise specified in the present specification, the weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

The hardmask composition according to some embodiments may help increase a carbon content by including a compound containing a large number of aromatic rings or heteroaromatic rings in one molecule. Accordingly, the hardmask layer obtained from the composition may have improved etch resistance. In addition, the compound may include a specific functional group on the aromatic ring or heteroaromatic ring, thereby improving the solubility of the compound containing a large number of aromatic rings or heteroaromatic rings in a solvent.

The hardmask composition according to some embodiments may include, e.g., a compound represented by Chemical Formula 1, and a solvent.

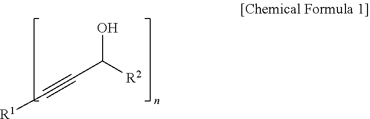

In Chemical Formula 1, R¹ may be or may include, e.g., a substituted or unsubstituted C6 to C20 aromatic hydrocarbon group.

R² may be or may include, e.g., a substituted or unsubstituted C6 to C30 aromatic hydrocarbon group, a substituted or unsubstituted C3 to C30 heteroaromatic group, or a combination thereof.

n may be, e.g., an integer of greater than or equal to 1 and does not exceed the valency of R¹. For example, if R¹ were to be a phenyl group, n may be an integer of 1 to 6.

In an implementation, when n is an integer of 2 or more, each R² may be the same as or different from each other.

The hardmask composition according to some embodiments may further increase the carbon content by directly linking the triple bond to the central aromatic ring group in the compound represented by Chemical Formula 1, and may help improve the crosslinking characteristics of the composition. In an implementation, the hardmask layer obtained from the composition may help secure excellent etch resistance. In an implementation, the compound may include a hydroxy group, and the compound may help improve the solubility of the compound containing a large number of aromatic rings or heteroaromatic rings in a solvent.

In an implementation, R¹ in Chemical Formula 1 may be, e.g., a substituted or unsubstituted C6 to C20 aromatic hydrocarbon group. In an implementation, R¹ in Chemical Formula 1 may be, e.g., a substituted or unsubstituted C6 to C14 aromatic hydrocarbon group. In an implementation, R¹ in Chemical Formula 1 may be, e.g., a substituted or unsubstituted C6 to C20 aromatic hydrocarbon group of a moiety of Group 1.

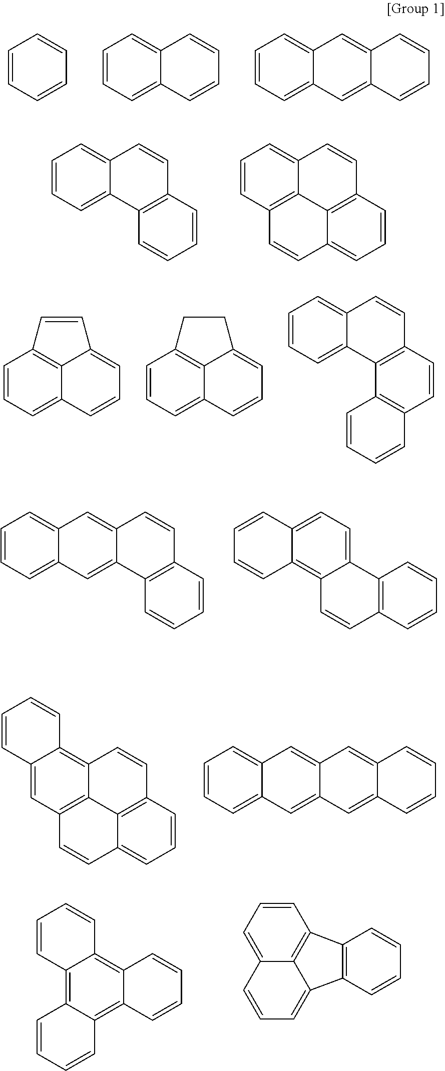

In an implementation, R¹ in Chemical Formula 1 may be, e.g., a substituted or unsubstituted C6 to C20 aromatic hydrocarbon group of a moiety of Group 1-1.

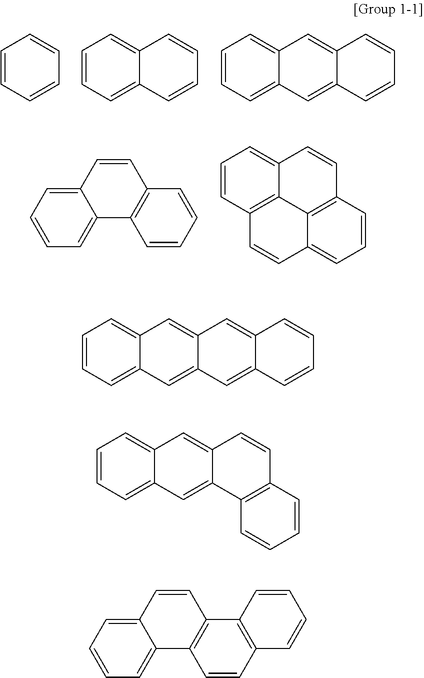

In an implementation, R¹ in Chemical Formula 1 may be, e.g., a substituted or unsubstituted benzene or phenyl group, a substituted or unsubstituted naphthyl group, or substituted or unsubstituted pyrenyl. group.

In an implementation, R² in Chemical Formula 1 may be, e.g., a substituted or unsubstituted C6 to C30 aromatic hydrocarbon group, a substituted or unsubstituted C6 to C30 heteroaromatic group, or a combination thereof. In an implementation, R² may be, e.g., a substituted or unsubstituted C10 to C30 aromatic hydrocarbon group, a substituted or unsubstituted C6 to C30 heteroaromatic group, or a combination thereof. In an implementation, R² may be, e.g., a substituted or unsubstituted C10 to C30 aromatic hydrocarbon group of a moiety of Group 2 or a substituted or unsubstituted C6 to C30 heteroaromatic group of a moiety of Group 3.

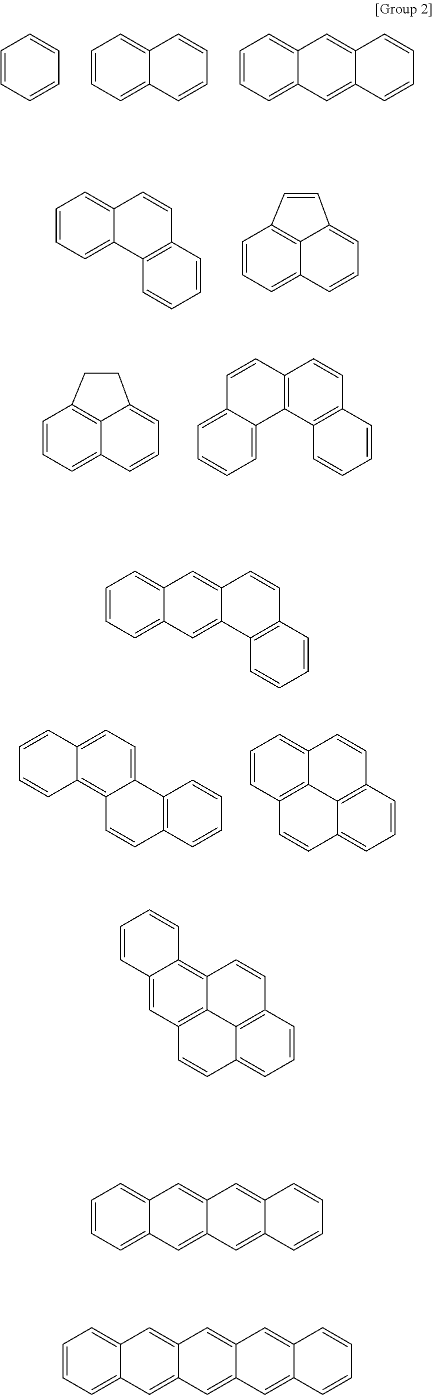

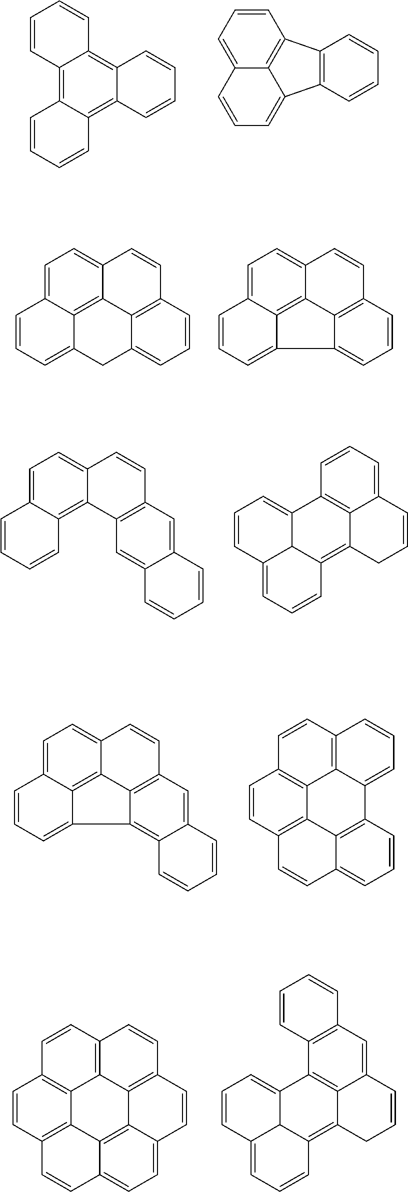

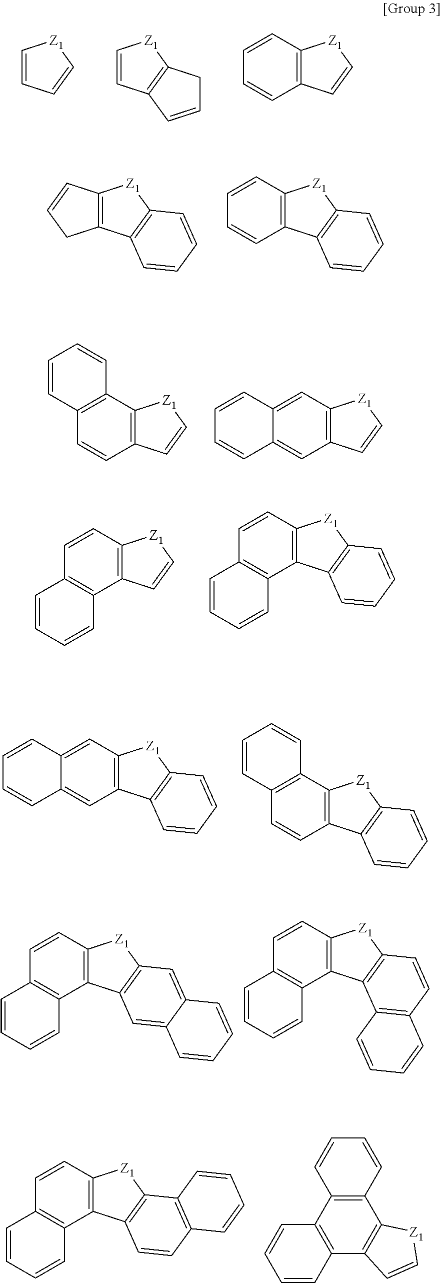

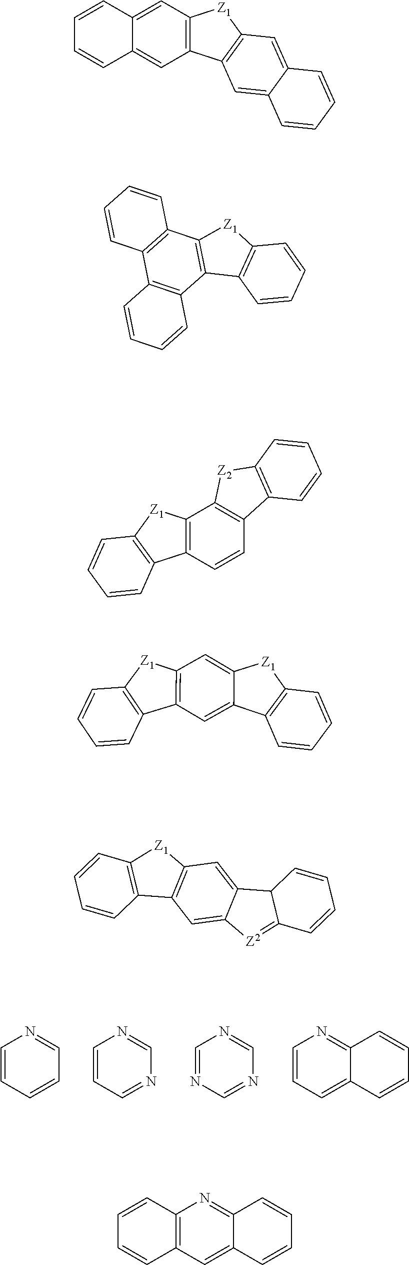

In Group 3, Z¹ and Z² may each independently be, e.g., —O—, —S—, —NR′—, in which R′ may be hydrogen, deuterium, or a substituted or unsubstituted C1 to C10 alkyl group, or a combination thereof.

In an implementation, R² in Chemical Formula 1 may be, e.g., a substituted or unsubstituted C10 to C30 aromatic hydrocarbon group. In an implementation, R² in Chemical Formula 1 may be, e.g., an aromatic hydrocarbon group containing 4 or more rings. In an implementation, R² in Chemical Formula 1 may be, e.g., a substituted or unsubstituted C10 to C30 aromatic hydrocarbon group of a moiety of Group 2-1.

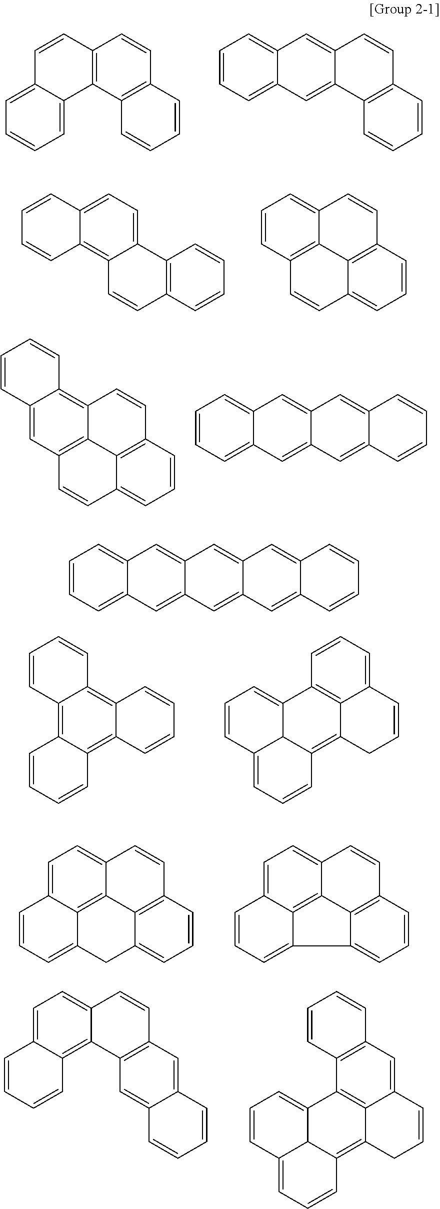

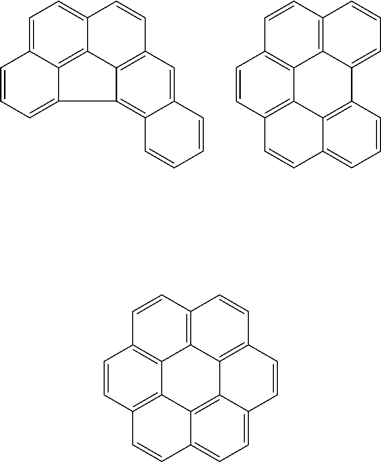

In an implementation, R² may include, e.g., a pyrene moiety, a perylene moiety, a benzoperylene moiety, or a coronene moiety. In an implementation, R² may include a moiety having one of the above structures, and etch resistance of a hardmask layer manufactured from a composition including it can be increased.

In Chemical Formula 1, n may be an integer of 1 or more and does not exceed the valency of R¹. The valence number refers to the number at which R¹ can be bonded with another linking group. In an implementation, n may be, e.g., an integer of 1 to 6, an integer of 1 to 4, an integer of 1 to 3, 1 or 2, or 2. In an implementation, n may be an integer of 2 or more, and the 2 or more R²s may be the same as or different from each other.

In an implementation, the compound represented by Chemical Formula 1 may be represented by, e.g., one of Chemical Formula 1-1 to Chemical Formula 1-3.

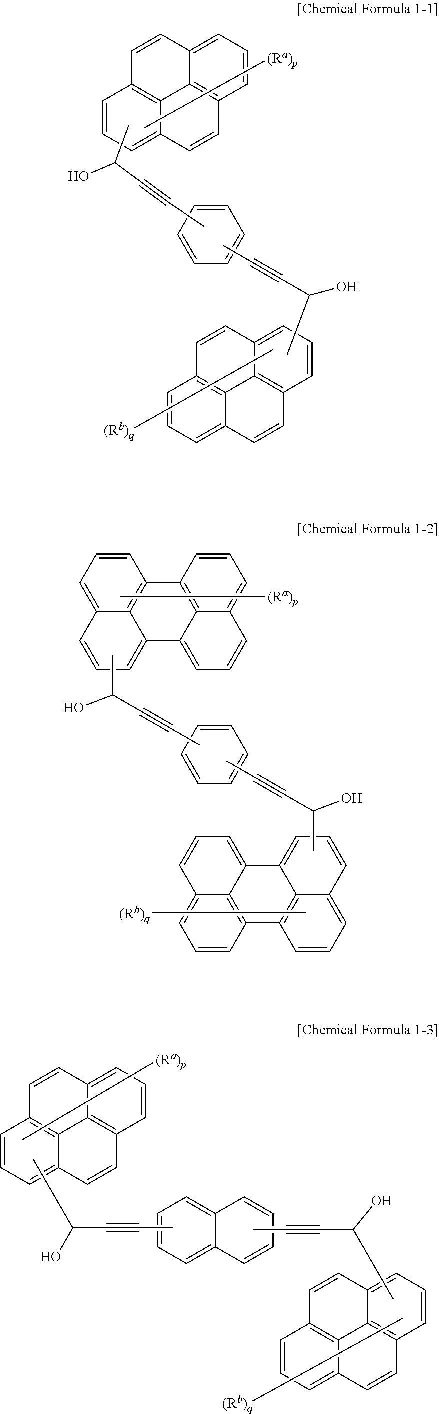

In Chemical Formula 1-1 to above Chemical Formula 1-3, R^{a} and R^{b} may each independently be, e.g., a hydroxy group, a substituted or unsubstituted C1 to C5 alkoxy group, a halogen atom, an amino group, a thiol group, or a combination thereof. p and q may each independently be, e.g., an integer of 0 to 10.

In an implementation, R^{a} and R^{b} may each independently be, e.g., a hydroxy group, a methoxy group, an ethoxy group, or a thiol group. In an implementation, R^{a} and R^{b} may each independently be, e.g., a hydroxy group or a methoxy group. p and q may each independently be, e.g., an integer of 0 to 5, or an integer of 0 to 2.

The compound may have a molecular weight of, e.g., about 300 g/mol to about 5,000 g/mol. In an implementation, the compound may have a molecular weight of, e.g., about 300 g/mol to about 4,500 g/mol, about 300 g/mol to about 4,000 g/mol, about 350 g/mol to about 4,500 g/mol, about 350 g/mol to about 4,000 g/mol, about 400 g/mol to about 5,000 g/mol, about 400 g/mol to about 4,500 g/mol, about 400 g/mol to about 4,000 g/mol, or about 400 g/mol to about 3,500 g/mol. By having a molecular weight within the above ranges, the carbon content and solubility in the solvent of the hardmask composition including the above compound may be adjusted and optimized.

The compound may be included in an amount of, e.g., about 0.1 wt % to about 30 wt %, based on a total weight of the hardmask composition. In an implementation, the compound may be included in an amount of, e.g., about 0.2 wt % to about 30 wt %, about 0.5 wt % to about 30 wt %, about 1 wt % to about 30 wt %, about 1 wt % to about 25 wt %, or about 1 wt % to about 20 wt %. By including the compound within the above ranges, a thickness, a surface roughness, and a planarization degree of the hardmask may be easily adjusted.

The hardmask composition according to some embodiments may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. In an implementation, the solvent may be a suitable solvent that has sufficient solubility and/or dispersibility for the compound.

In an implementation, the hardmask composition may further include an additive, e.g., a surfactant, a crosslinking agent, a thermal acid generator, or a plasticizer.

The surfactant may include, e.g., a fluoroalkyl compound, alkylbenzenesulfonate, alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may include, e.g., an acid compound such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

In an implementation, a hardmask layer including a cured product of the aforementioned hardmask composition may be provided.

Hereinafter, a method of forming patterns using the aforementioned hardmask composition is described.

A method of forming patterns according to some embodiments may include providing a material layer on a substrate, applying a hardmask composition including the aforementioned compound and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., a silicon wafer, a glass substrate, or a polymer substrate. The material layer may be a material to be finally patterned, e.g., a metal layer such as an aluminum layer or a copper layer, a semiconductor layer such as a silicon layer, or an insulation layer such as a silicon oxide layer or a silicon nitride layer. The material layer may be formed through a method such as a chemical vapor deposition (CVD) process.

The hardmask composition may be the same as described above, and may be applied by spin-on coating in a form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process and a second heat-treating process.

In an implementation, the heat-treating of the hardmask composition may include, e.g., one heat-treating process performed at about 100° C. to about 1,000° C. for about 10 seconds to about 1 hour. In an implementation, the heat-treating may be performed under an atmosphere of air or nitrogen, or an atmosphere having oxygen concentration of 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 150° C. to about 400° C. for about 30 seconds to about 1 hour, about 30 seconds to about 30 minutes, about 30 seconds to about 10 minutes, or about 30 seconds to about 5 minutes.

In an implementation, the heat-treating of the hardmask composition may include, e.g., a second heat-treating process performed at about 100° C. to 1,000° C., about 300° C. to about 1,000° C., about 500° C. to about 1,000° C., or about 500° C. to about 600° C. for about 30 seconds to about 1 hour, about 30 seconds to about 30 minutes, about 30 seconds to about 10 minutes, or about 30 seconds to about 5 minutes, consecutively. In an implementation, the first and second heat-treating process may be performed under an air or nitrogen atmosphere, or may be performed under an atmosphere with an oxygen concentration of 1 wt % or less.

By performing at least one of the steps of heat-treating the hardmask composition at a high temperature, e.g., of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include at a first heat-treating process, a second heat-treating process, a UV/Vis curing process, or a near IR curing process, or may include two or more processes consecutively.

In an implementation, the method may further include forming a silicon-containing thin layer on the hardmask layer. The silicon-containing thin layer may be formed of, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may include, e.g., N₂/O₂, CHF₃, CF₄, Cl₂, BCl₃, or a mixed gas thereof.

The etched material layer may be formed in a plurality of patterns, and the plurality of patterns may include a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Compounds

### Synthesis Example 1

Under a nitrogen atmosphere, 3 mmol (0.33 mL) of 1,4-diethynylbenzene, 1.5 mmol (0.75 mL) of diethyl zinc, and 4 mL of toluene were added to a flask, and then stirred at 120° C. for 5 hours. After cooling to 0° C., 1 mmol (230 mg) of pyrene-1-carboxaldehyde was dissolved in 10 mL of toluene, and this solution was slowly added thereto over 20 minutes and then, stirred at ambient temperature for 12 hours. Whether a reaction was completed was checked through thin layer chromatography (TLC), 10 mL of a saturated chloride ammonium (NH₄Cl) aqueous solution was added to an intermediate product therefrom, and an organic layer was extracted therefrom with ethyl acetate, dried by using sodium sulfate (Na₂SO₄), and purified through column chromatography to obtain a compound represented by Chemical Formula 2.

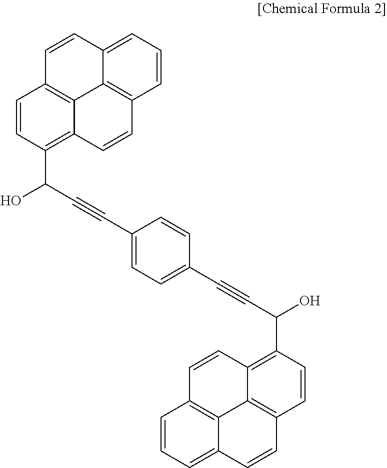 [SMILES: OC(C#Cc1ccc(C#CC(O)c2ccc3ccc4cccc5ccc2c3c45)cc1)c1ccc2ccc3cccc4ccc1c2c34]

### Synthesis Example 2

A compound represented by Chemical Formula 3 was obtained in the same manner as in Synthesis Example 1 except that perylene-1-carboxaldehyde was used instead of the pyrene-1-carboxaldehyde.

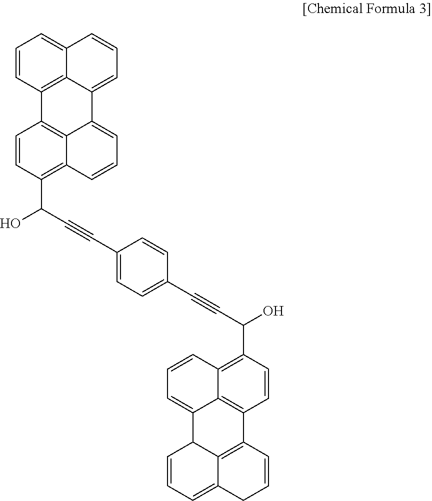 [SMILES: OC(C#Cc1ccc(C#CC(O)c2ccc3c4cccc5cccc(c6cccc2c63)c54)cc1)c1ccc2c3c(cccc13)C1C=CC=C3CC=CC2=C31]

### Synthesis Example 3

A compound represented by Chemical Formula 4 was obtained in the same manner as in Synthesis Example 1 except that 2,7-diethynylnaphthalene was used instead of the 1,4-diethynylbenzene.

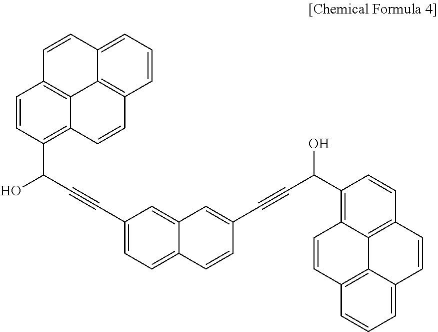 [SMILES: OC(C#Cc1ccc2ccc(C#CC(O)c3ccc4ccc5cccc6ccc3c4c56)cc2c1)c1ccc2ccc3cccc4ccc1c2c34]

### Synthesis Example 4

A compound represented by Chemical Formula 5 was obtained in the same manner as in Synthesis Example 1 except that 2,7-diethynylnaphthalene instead of the 1,4-diethynylbenzene and 6-hydroxypyrene-1-carbaldehyde instead of the pyrene-1-carboxaldehyde were used.

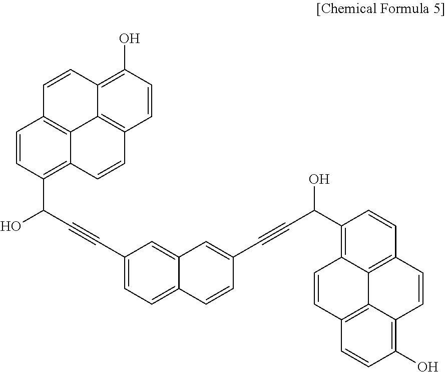 [SMILES: Oc1ccc2ccc3c(C(O)C#Cc4ccc5ccc(C#CC(O)c6ccc7ccc8c(O)ccc9ccc6c7c98)cc5c4)ccc4ccc1c2c43]

### Comparative Synthesis Example 1

Under a nitrogen atmosphere, 3 mmol (0.33 mL) of divinylbenzene), 1.5 mmol (0.75 mL) of diethyl zinc, and 4 mL of toluene were added to a flask, and then stirred at 120° C. for 5 hours. After cooling to 0° C., 1 mmol (230 mg) of pyrene-1-carboxaldehyde was dissolved in 10 mL of toluene, and the solution was slowly added thereto over 20 minutes and then, stirred at ambient temperature for 12 hours. Whether a reaction was completed was checked through thin layer chromatography (TLC), 10 mL of a saturated ammonium chloride (NH₄Cl) aqueous solution was added to an intermediate product therefrom, and an organic layer was extracted therefrom with ethyl acetate, dried with sodium sulfate (Na₂SO₄), and purified through column chromatography to obtain a compound represented by Chemical Formula 6.

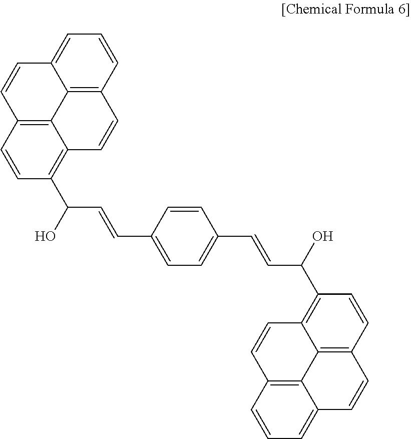 [SMILES: OC(/C=C/c1ccc(/C=C/C(O)c2ccc3ccc4cccc5ccc2c3c45)cc1)c1ccc2ccc3cccc4ccc1c2c34]

### Comparative Synthesis Example 2

A compound represented by Chemical Formula 7 was obtained in the same manner as in Comparative Synthesis Example 1 except that 6-hydroxypyrene-1-carbaldehyde instead of the pyrene-1-carboxaldehyde was used.

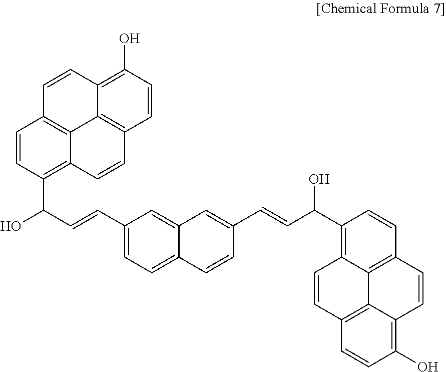 [SMILES: Oc1ccc2ccc3c(C(O)/C=C/c4ccc5ccc(/C=C/C(O)c6ccc7ccc8c(O)ccc9ccc6c7c98)cc5c4)ccc4ccc1c2c43]

### Preparation of Hardmask Composition

### Example 1

A hardmask composition was prepared by dissolving 3.5 g of the compound represented by Chemical Formula 2 according to Synthesis Example 1 in 10 g of a solvent of propylene glycol methyletheracetate and cyclohexanone mixed in a ratio of 7:3 and filtering the solution with a syringe filter.

### Example 2

A hardmask composition was prepared in the same manner as in Example 1 except that the compound represented by Chemical Formula 3 instead of Chemical Formula 2 was used.

### Example 3

A hardmask composition was prepared in the same manner as in Example 1 except that the compound represented by Chemical Formula 4 instead of Chemical Formula 2 was used.

### Example 4

A hardmask composition was prepared in the same manner as in Example 1 except that the compound represented by Chemical Formula 5 instead of Chemical Formula 2 was used.

### Comparative Example 1

A hardmask composition was prepared in the same manner as in Example 1 except that the compound represented by Chemical Formula 6 instead of Chemical Formula 2 was used.

### Comparative Example 2

A hardmask composition was prepared in the same manner as in Example 1 except that the compound represented by Chemical Formula 7 instead of Chemical Formula 2 was used.

### Evaluation 1: Etch Resistance

Each of the hardmask compositions of Examples 1 to 4 and Comparative Examples 1 and 2 (15% of a solid content in PGMEA or PGMEA/ANONE) was coated on a silicon wafer, heat-treated on a hot plate at 400° C. for 2 minutes to form a 4,000 Å-thick thin film, and then, measured with respect to a thickness by using a thin film thickness meter made by K-MAC Co., Ltd. Subsequently, the thin film was dry-etched by using CFx mixed gas and N₂/O₂ mixed gas and then, measured again with respect to a thickness. Each thickness of the thin film before and after the etching and etching time were used to calculate a bulk etch rate (BER) according to Calculation Equation 1, and the results are shown in Table 1.

$$[ Calculation Equation 1 ]$$

$$* Bulk Etch Rate [ Å / sec ] = ( initial thin film thickness ) - ( thin film thickness after etching ) [ Å ] / etching time [ s ]$$

TABLE 1

Bulk etch rate (Å/sec)

| | N₂/O₂ etch | CFx etch |
|---|---|---|
| Example 1 | 23.6 | 22.3 |
| Example 2 | 23.5 | 23.2 |
| Example 3 | 21.2 | 21.5 |
| Example 4 | 25.2 | 23.6 |
| Comparative Example 1 | 21 | 21.2 |
| Comparative Example 2 | 19.8 | 20.0 |

Referring to Table 1, the hardmasks formed of the hardmask compositions according to Examples 1 to 4 exhibited an equivalent etch rate during the N₂/O₂ mixed gas and CFx gas etching, compared with the hardmasks formed of the hardmask compositions according to the Comparative Examples. The hardmasks formed of the hardmask compositions according to Examples 1 to 4 exhibited equivalent etch resistance, compared with the hardmasks formed of the hardmask compositions according to the Comparative Examples.

### Evaluation 2: Crosslinking Characteristics

In order to evaluate cross-linking characteristics of the compositions according to Examples 1 to 4 and the Comparative Examples, an SC1 solution was prepared by mixing ammonia, hydrogen peroxide, and water in a ratio of 1:1:5.

Each of the hardmask compositions of Examples 1 to 4 and Comparative Examples 1 and 2 (10% of a solid content in PGMEA or PGMEA/ANONE) was coated on an Si substrate and then, heat-treated at 400° C. for 1 minute to form a 200 nm-thick hardmask layer. After dipping the Si substrate having the hardmask layer in an SC1 solution heated at 60° C. for 5 minutes, a film thickness was measured again to check whether the film was peeled off or not and thereby, evaluate cross-linking characteristics. The results are shown in Table 2.

TABLE 2

| | film thickness maintenance rate (%) |
|---|---|
| | after dipping in a SC1 solution |
| Example 1 | 100% |
| Example 2 | 100% |
| Example 3 | 100% |
| Example 4 | 100% |
| Comparative Example 1 | 86% |
| Comparative Example 2 | 88% |

Referring to Table 2, the hardmasks formed of the compositions according to Examples 1 to 4 exhibited no peeling after dipping in the SC1 solution, and the hardmasks formed of the compositions according to Comparative Examples 1 and 2 exhibited partial peeling. The hardmasks of the Examples exhibited improved cross-linking characteristics, compared with the hardmasks of the Comparative Examples.

By way of summation and review, according to small-sizing the pattern to be formed, it may be difficult to provide a fine pattern having an excellent profile by only using some lithographic techniques. Accordingly, an auxiliary layer, called a hardmask layer, may be formed between the material layer and the photoresist layer to provide a fine pattern.

This hardmask layer may serve as an interlayer that transfers a fine pattern of the photoresist through selective etching, and thus the hardmask layer may have etch resistance and crosslinking characteristics to withstand the etching process required for pattern transfer.

Some hardmask layers may be formed in a chemical or physical deposition method and may have low economic efficiency due to a large-scale equipment and a high process cost. A spin-coating technique for forming a hardmask layer has recently been considered. The spin-coating technique may be an easier process to conduct than the conventional method, and a hardmask layer formed therefrom may exhibit much more excellent gap-fill characteristics and planarization characteristics, but the etch resistance required for the hardmask layer may tend to decrease somewhat. Accordingly, a hardmask composition may be used to apply to the spin-coating technique and to secure equivalent etch resistance to that of the hardmask layer formed in the chemical or physical deposit method.

In order to improve the etch resistance of a hardmask layer, research on maximizing a carbon content of the hardmask composition is being made. As a carbon content of a compound included in the hardmask composition is maximized, solubility of the compound in a solvent may tend to decrease. A carbon content of the compound included in the hardmask composition may be maximized to help improve the etch resistance of the hardmask layer formed therefrom, while not reducing the solubility of the compound in the solvent.

One or more embodiments may provide a hardmask composition, a hardmask layer including a cured product of the hardmask composition, and a method of forming patterns using the hardmask composition.

One or more embodiments may provide a hardmask composition that can be effectively applied to a hardmask layer.

The hardmask composition according to some embodiments may have excellent solubility in solvents and can be effectively applied to a hardmask layer.

The hardmask composition according to some embodiments may have excellent crosslinking characteristics, and the hardmask layer formed from the composition may help secure excellent etch resistance.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a compound represented by Chemical Formula 1; and
a solvent, 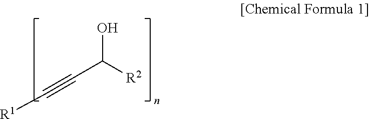
wherein, in Chemical Formula 1,
R¹ is a substituted or unsubstituted C6 to C20 aromatic hydrocarbon group,
R² is a substituted or unsubstituted C6 to C30 aromatic hydrocarbon group, a substituted or unsubstituted C3 to C30 heteroaromatic group, or a combination thereof,
n is an integer of greater than or equal to 1 and does not exceed the valency of R¹, and
when n is an integer of 2 or more, each R² is the same or different from each other.

2. The hardmask composition as claimed in claim 1, wherein, in Chemical Formula 1, R² is a substituted or unsubstituted C10 to C30 aromatic hydrocarbon group, a substituted or unsubstituted C6 to C30 heteroaromatic group, or a combination thereof.

3. The hardmask composition as claimed in claim 1, wherein in Chemical Formula 1, R¹ is a substituted or unsubstituted C6 to C14 aromatic hydrocarbon group, R² is a substituted or unsubstituted C10 to C30 aromatic hydrocarbon group, and n is 2.

4. The hardmask composition as claimed in claim 1, wherein in Chemical Formula 1, R¹ is a substituted or unsubstituted C6 to C20 aromatic hydrocarbon group of a moiety of Group 1:

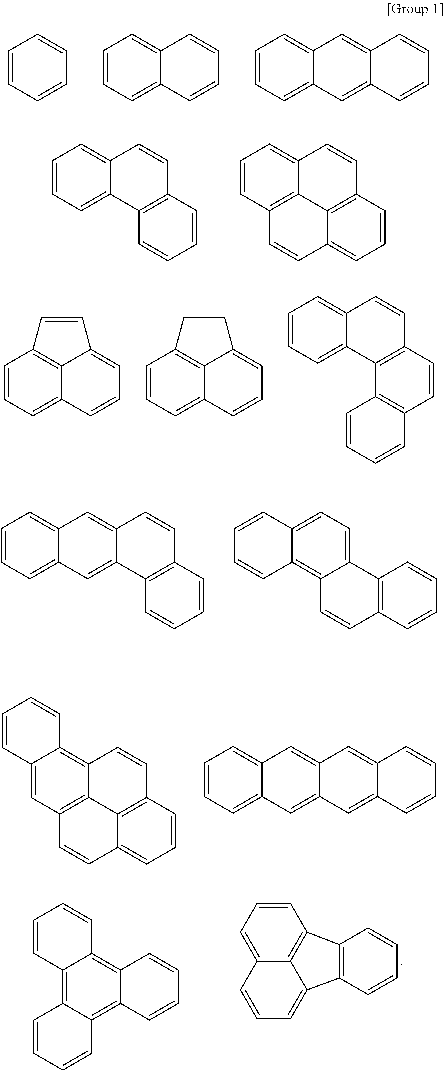

5. The hardmask composition as claimed in claim 1, wherein:
in Chemical Formula 1, R² is a substituted or unsubstituted C6 to C30 aromatic hydrocarbon group of a moiety of Group 2 or a substituted or unsubstituted C3 to C30 heteroaromatic group of a moiety of Group 3: 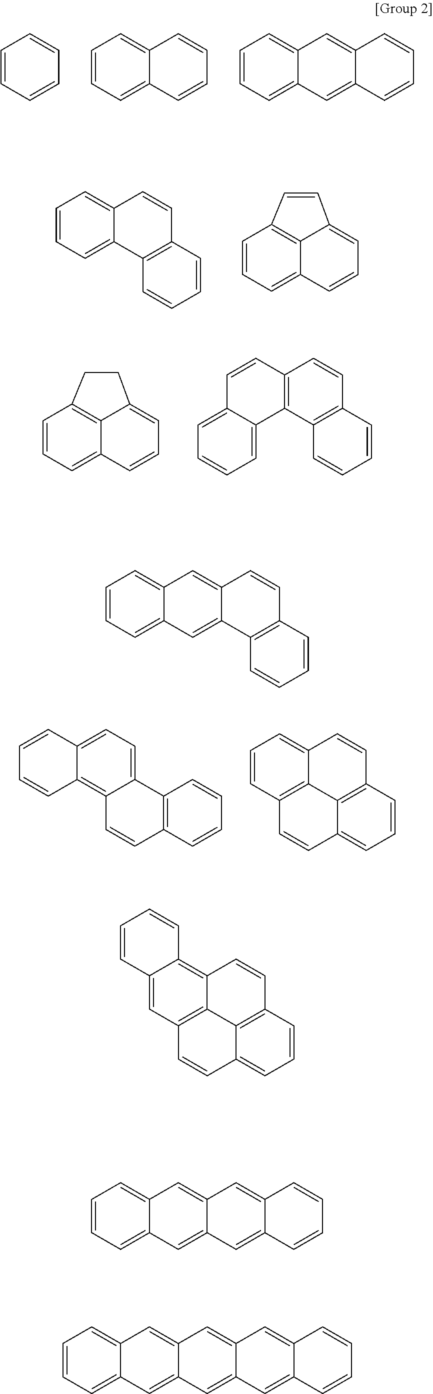 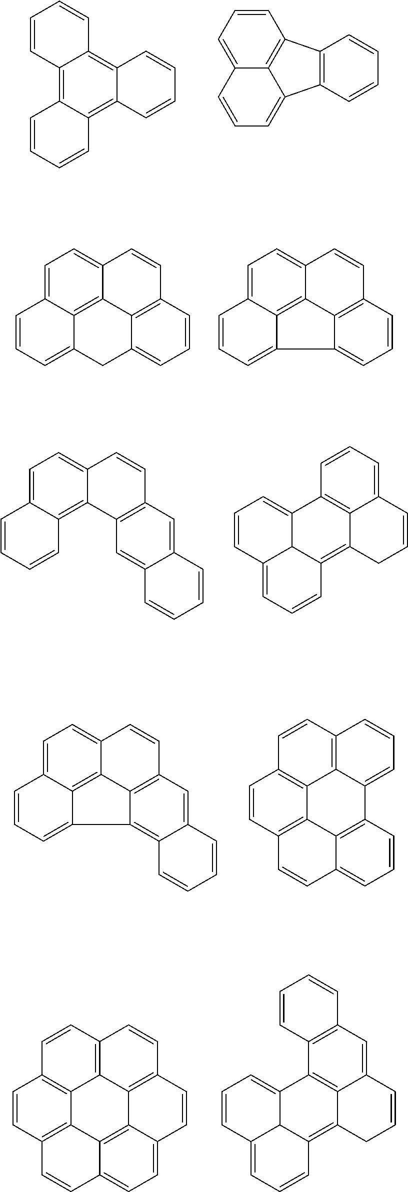 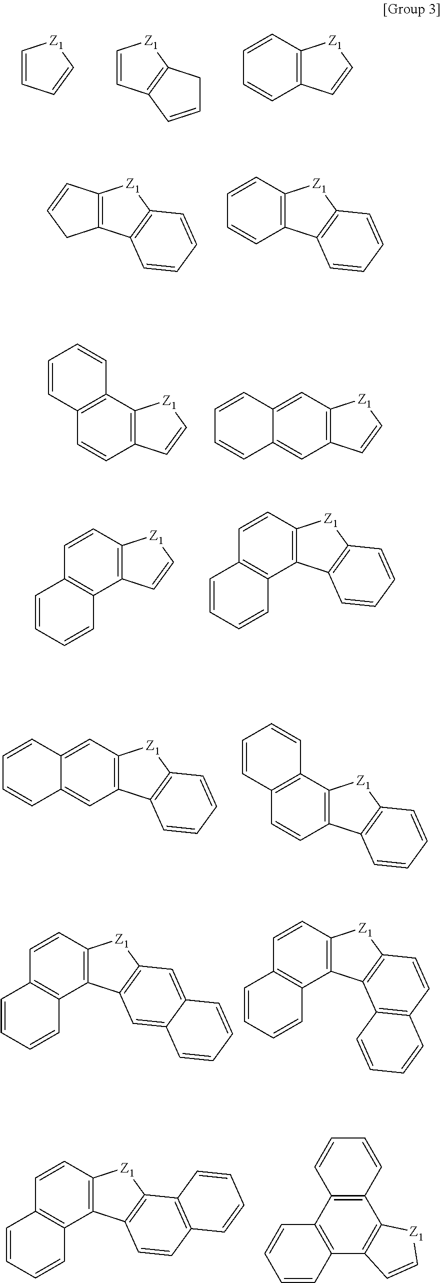 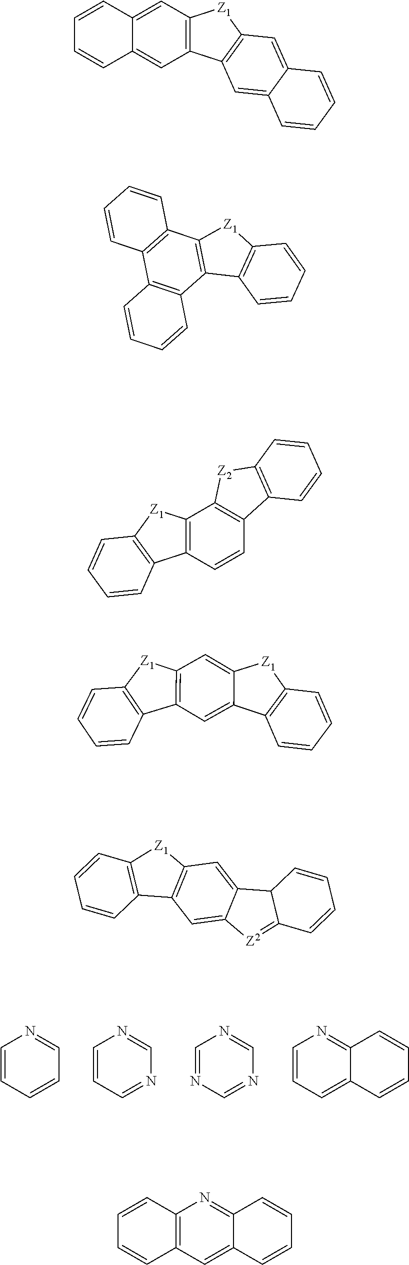
in Group 3, Z¹ and Z² are each independently —O—, —S—, —NR′—, in which R′ is hydrogen, deuterium, or a substituted or unsubstituted C1 to C10 alkyl group, or a combination thereof.

6. The hardmask composition as claimed in claim 1, wherein in Chemical Formula 1,
R¹ is substituted or unsubstituted C6 to C20 aromatic hydrocarbon group of a moiety of Group 1-1, and
R² is a substituted or unsubstituted C6 to C30 aromatic hydrocarbon group of a moiety of Group 2-1,

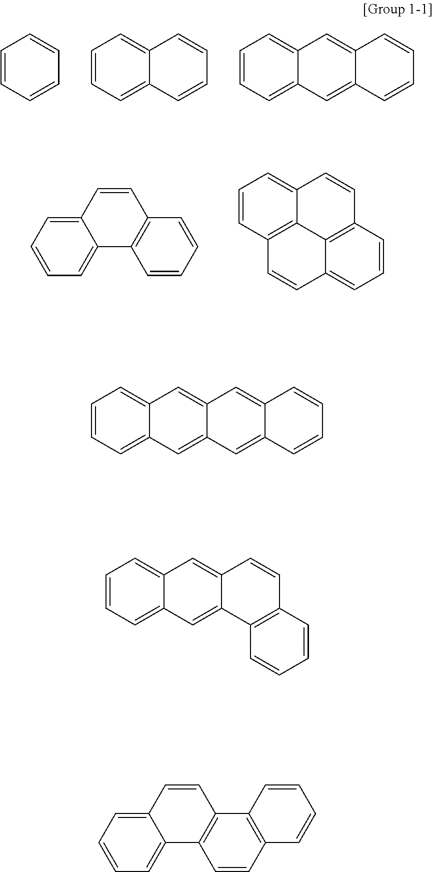

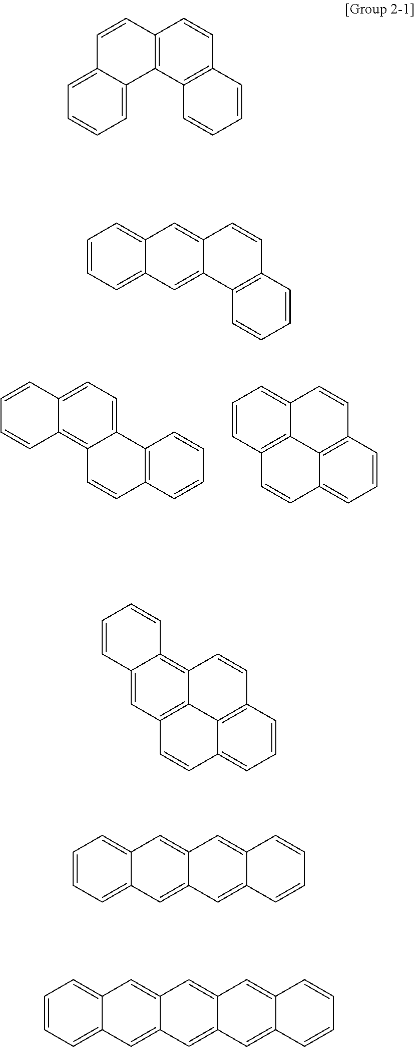

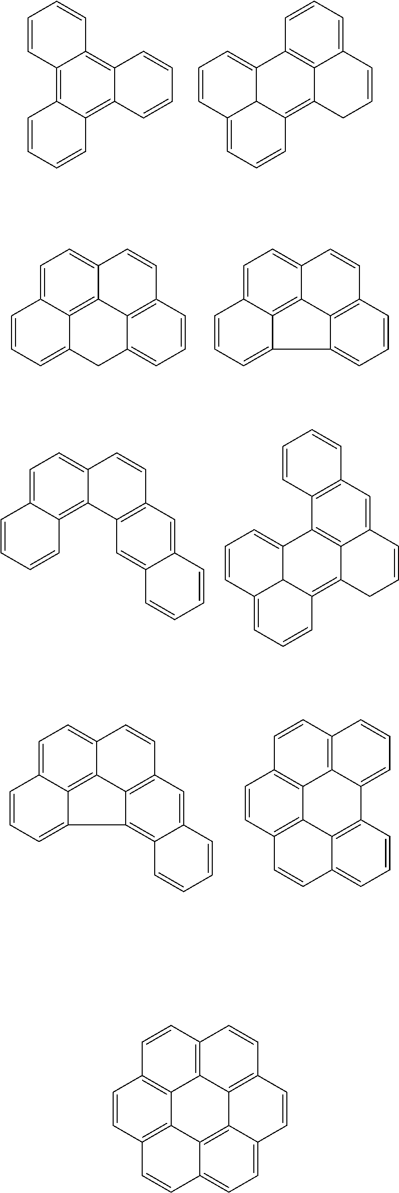

7. The hardmask composition as claimed in claim 1, wherein, in Chemical Formula 1, n is 2 and each R² is the same.

8. The hardmask composition as claimed in claim 1, wherein:
the compound represented by Chemical Formula 1 is represented by one of Chemical Formula 1-1 to Chemical Formula 1-3: 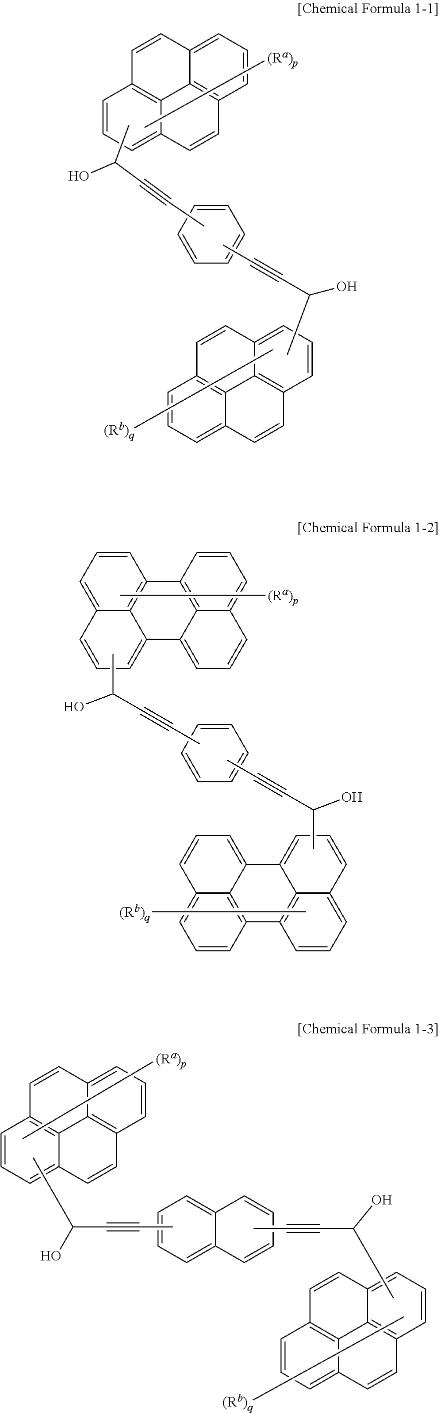
in Chemical Formula 1-1 to Chemical Formula 1-3,
R^{a} and R^{b} are each independently a hydroxy group, a substituted or unsubstituted C1 to C5 alkoxy group, a halogen atom, an amino group, a thiol group, or a combination thereof, and
p and q are each independently an integer of 0 to 10.

9. The hardmask composition as claimed in claim 1, wherein the compound has a molecular weight of about 300 g/mol to about 5,000 g/mol.

10. The hardmask composition as claimed in claim 1, wherein the compound is included in an amount of about 0.1 wt % to about 30 wt %, based on a total weight of the hardmask composition.

11. The hardmask composition as claimed in claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

12. A hardmask layer comprising a cured product of the hardmask composition as claimed in claim 1.

13. A method of forming patterns, the method comprising:
providing a material layer on a substrate;
applying the hardmask composition as claimed in claim 1 to the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

14. The method as claimed in claim 13, wherein forming the hardmask layer includes heat-treating at about 100° C. to about 1,000° C.
